(19) United States
(12) Patent Application Publication
(10) Pub. No.: US 2026/0309786 A1
(43) Pub. Date: Oct. 8, 2026

(54) SYSTEMS AND METHODS FOR CELL-BASED MODELING PERFORMANCE OF A BATTERY PACK

(71) Applicant: Electra Vehicles, Inc., Boston, MA (US)

(72) Inventors: Mina Gamal Naguib Nassim, Hamilton (CA); Peter Kei, Coventry, RI (US); David Aaron Rivkin, Boston, MA (US); Fabrizio Martini, Boston, MA (US); Nicholas Alexander Price, London (GB); Edoardo Catenaro, Rome (IT); Noah M. Johnson, Philadelphia, PA (US)

(21) Appl. No.: 19/582,878

(22) PCT Filed: Oct. 30, 2024
(86) PCT No.: PCT/US2024/053625

§ 371 Date: Apr. 29, 2026

Related U.S. Application Data
(60) Provisional application No. 63/594,764, filed on Oct. 31, 2023.

(51) Int. Cl. G01R 31/367; G01R 31/3842; G01R 31/392; G01R 31/396

(52) U.S. Cl. CPC G01R 31/367; G01R 31/3842; G01R 31/392; G01R 31/396

(57) ABSTRACT

Methods and apparatus for generating an updated machine learning model for predicting a property of an energy storage system. The method includes receiving sensor data associated with an energy storage system, transforming, using at least one hardware computer processor, the sensor data into cell-level data for a number of representative cells in the energy storage system, generating, using at least one model of cell degradation and the cell-level data, synthetic cell-level data for each of the representative cells, training a machine learning (ML) model based on the cell-level data and the synthetic cell-level data, and outputting the trained ML model, wherein the trained ML model is configured to predict a property of the energy storage system based on cell-level data.

### FIELD OF INVENTION

This disclosure relates to techniques for cell-based modelling to assess performance measures of a battery pack.

### BACKGROUND

Some battery-powered devices, such as electric vehicles, manage their available energy by estimating quantities that are indicative of the current state of their energy storage system (e.g., batteries). Example quantities that are often used in assessing available energy in a battery-powered device include State of Health (SOH), State of Charge (SOC), State of Power (SOP), and State of Temperature (SOT). Because the current state of such quantities is not directly measurable, they are typically estimated. Some conventional techniques estimate these properties using a static model of the energy storage system that is determined when the battery-powered device is manufactured. For example, Coulomb counting techniques employed by some battery-powered devices to estimate the current state of their energy storage system use analytical methods to statistically estimate the future state of the battery following manufacture.

### SUMMARY

Accurately estimating one or more properties (e.g., SOH, SOC, SOP, SOT, etc., collectively “SOX”) for an energy storage system (e.g., a battery) in an electric vehicle or other system (e.g., a robot, a stationary energy storage system) may, among other things, provide the user of the device with accurate information about the current charge state of the device, facilitate the avoidance of a catastrophic failure of the device, and/or improve or optimize control strategies for energy system usage of the device. Some existing techniques for estimating properties of an energy storage system rely on models that are not dynamically updated based on current information about the energy storage system, resulting in inaccurate estimates of the properties. Some embodiments of the present disclosure improve upon existing techniques for estimating properties of an energy storage system by using an adaptive cell model that considers cell-level information for the cells in the energy storage system. The adaptive cell model may be configured to estimate a value for one or more properties of an energy storage system based on sensor data and/or synthetic sensor data associated with the energy storage system.

Some embodiments of the present disclosure relate to a computer-implemented method. The computer-implemented method includes receiving sensor data associated with an energy storage system, and transforming, using at least one hardware computer processor, the sensor data into cell-level data for a number of representative cells in the energy storage system.

In one aspect, the method further includes generating, using at least one model of cell degradation and the cell-level data, synthetic cell-level data for each of the representative cells, training a machine learning (ML) model based on the cell-level data and the synthetic cell-level data, wherein the trained ML model is configured to infer a property of the energy storage system based on cell-level data, and outputting the trained ML model. In another aspect, the energy storage system is a battery pack and the received sensor data is associated with the battery pack. In another aspect, the sensor data includes module sensor data associated with a module of the battery pack, the module including a plurality of cells, and transforming the sensor data into cell-level data for a representative number of cells comprises using a module model to transform the module sensor data into cell-level data. In another aspect, the sensor data includes pack sensor data associated with all cells in the battery pack, and transforming the sensor data into cell-level data for a representative number of cells comprises using a pack model to transform the pack sensor data into cell-level data.

In another aspect, the sensor data includes one or more of voltage sensor data, current sensor data, temperature sensor data, or pressure sensor data. In another aspect, the sensor data comprises time-series data. In another aspect, transforming the sensor data into cell-level data for a number of representative cells in the energy storage system includes processing the sensor data using one or more models to produce cell-level data for a plurality of cells in the energy storage system, generating groups of cells based on the cell-level data, and selecting a representative cell from each of the groups of cells to produce the cell-level data for a number of representative cells in the energy storage system. In another aspect, transforming the sensor data into cell-level data for a number of representative cells in the energy storage system further includes assigning scores to the plurality of cells in the energy storage system, wherein generating the groups of cells is performed based, at least in part, on the scores.

In another aspect, generating synthetic cell-level data for each of the representative cells includes providing the cell-level data as input to the at least one model of cell degradation, the at least one model of cell degradation including degradation parameters that describe how cells in the energy storage system degrade over time, and generating the synthetic cell-level data based, at least in part, on an output of the at least one model of cell degradation. In another aspect, training the ML model comprises sequentially training the ML model based on the cell-level data and the synthetic cell-level data for each of the representative cells. In another aspect, outputting the trained ML model comprises transferring the trained ML model to a battery management system associated with the energy storage system. In another aspect, the method further includes transferring to the battery management system, a mapping model configured to translate sensor data from the battery management system into cell-level data for representative cells of the energy storage system. In another aspect, the method further includes generating the mapping model based, at least in part, on second cell-level data for the number of representative cells and second sensor data. In another aspect, generating the mapping model is further based, at least in part, on at least one degradation parameter associated with the at least one model of cell degradation. In another aspect, the trained ML model is configured to infer one or more of state of charge (SOC), state of health (SOH), state of power (SOP), or state of temperature (SOT) of the energy storage system.

Some embodiments of the present disclosure relate to a computer-implemented method for estimating a property of an energy storage system. The method includes receiving sensor data associated with the energy storage system, transforming, using a mapping model executing on at least one hardware computer processor, the sensor data into cell-level data for representative cells of the energy storage system, providing the cell-level data as input to a trained machine learning (ML) model, and estimating the property of the energy storage system using the trained ML model.

In one aspect, the method further includes receiving from a network-connected computing device, an updated trained ML model and an updated mapping model, transforming the sensor data into cell-level data for representative cells of the energy storage system is performed using the updated mapping model, and estimating the property of the energy storage system is based, at least in part, on an output of the updated trained ML model. In another aspect, the property is selected from the group consisting of state of charge (SOC), state of health (SOH), state of power (SOP), and state of temperature (SOT) of the energy storage system. In another aspect, the sensor data includes one or more of voltage sensor data, current sensor data, temperature sensor data, or pressure sensor data. In another aspect, the sensor data comprises time-series data.

Some embodiments of the present disclosure relate to a computer-implemented method. The method includes receiving first sensor data associated with an energy storage system, transforming, using at least one hardware computer processor, the first sensor data into cell-level data for a number of representative cells in the energy storage system, generating a mapping model configured to transform second sensor data into cell-level data for representative cells in the energy storage system, wherein the mapping model is generated based, at least in part, on the cell-level data for the number of representative cells and the first sensor data, and outputting the generated mapping model.

In one aspect, generating the mapping model is further based, at least in part, on at least one degradation parameter associated with at least one model of cell degradation. In another aspect, outputting the generated mapping model includes transferring the generated mapping model to a battery management system associated with the energy storage system.

Some embodiments of the present disclosure relate to a system. The system includes at least one computer processor, and at least one computer-readable medium having stored thereon instructions which, when executed, program the at least one computer processor to perform any of the methods described herein.

Some embodiments of the present disclosure relate to at least one computer-readable medium having stored thereon instructions which, when executed, program at least one computer processor to perform any of the methods described herein.

There is no general consensus as to what type of model system (e.g., architecture, optimization process, data preparation/post-processing) would be ideal for a modern high-voltage battery pack system. In the context of combining physics-informed modelling with machine learning (ML) battery modeling, little is known as to how a baseline model (e.g., a template/starting model that is trained on simulation data (e.g., generated using physics-informed models), and not yet seen real-data) should be prepared in a way that would generalize the model, and allow the baseline model to perform in undefined and unexpected conditions (e.g., varying weather, temperature, degradation/SOH states that was neither fully described by simulated physics data nor real experimental data). Some embodiments of the present disclosure relate to a methodology for generating model(s) (including but not limited to the baseline model) that perform comparably with industry leading Extended Kalman Filter (EKF) algorithms for estimation of one or more properties (e.g., SOC, SOH, SOP, SOT, etc. (collectively referred to herein as “SOX”)) of an energy storage system. A real-time algorithm (ML or similar deployable logic), an example of which is described herein, that is more performant than industry-leading EKF in terms of SOX estimation may solve issues related to inaccurate/imprecise quantification of internal battery cell states that would cause resource waste including, not limited to, overcharging, higher safety risk, higher than expected battery degradation rate over the entire life of the pack. Ultimately, the data decomposition/composition processes described herein may generate one or more competitive SOX models designed to be deployed onto the battery management system (BMS) of a commercial vehicle, and may be utilized for providing key insights into pack internal states/dynamics (e.g., Pack Capacity, “Pack-SOX”, Pack Imbalance, etc.).

### BRIEF DESCRIPTION OF THE DRAWINGS

FIG. 1 schematically illustrates an adaptive cell model, in accordance with some embodiments of the present disclosure;

FIG. 2 schematically illustrates incorporation of an adaptive cell model in an energy storage management system, in accordance with some embodiments of the present disclosure;

FIG. 3A schematically illustrates an architecture for updating a property model for an energy storage system using cell-level signals, in accordance with some embodiments of the present disclosure;

FIG. 3B schematically illustrates components in a process for decomposing signals from a battery management system to cell-level data for representative cells in an energy storage system, in accordance with some embodiments of the present disclosure;

FIG. 3C schematically illustrates a process for decomposing different types of signals to cell-level data, in accordance with some embodiments of the present disclosure;

FIG. 3D schematically illustrates components in a process for using a mapping model and a trained model to estimate a property of an energy storage system, in accordance with some embodiments of the present disclosure;

FIG. 4 schematically illustrates an architecture for updating an energy storage system property estimation model, in accordance with some embodiments of the present disclosure;

FIG. 5 is a flowchart of a process for generating an updated property model based on cell-level data, in accordance with some embodiments of the present disclosure;

FIG. 6 is a flowchart of a process for using a mapping model and a trained model to estimate a property of an energy storage system, in accordance with some embodiments of the present disclosure; and

FIG. 7 schematically illustrates a computing architecture on which some embodiments of the present disclosure may be implemented.

### DETAILED DESCRIPTION

As described above, information about the current state of an energy storage system (e.g., one or more battery packs) in a battery-powered vehicle, such as the system's SOH, SOC, SOP and/or SOT is not directly measurable without destroying the battery. Accordingly, such quantities may be estimated using one or more models that attempt to capture how characteristics of the energy storage system are expected to change over time as the energy storage system is used.

Devices (e.g., electric vehicles) that incorporate energy storage systems (e.g., battery packs) typically include a battery management system (BMS), which monitors and controls individual cells or groups of cells within the battery pack. Some technologies utilize signals from the BMS, such as minimum, maximum, and average values, to determine the state of the battery pack without considering the state of individual cells in the battery pack. While these methods offer some insights about the state of the battery pack, they are highly susceptible to sensor noise. Moreover, such techniques fail to account for additional factors within the battery pack that influence the measured signals, such as contact resistance, busbar resistance, and thermal management.

Other techniques group cells together and employ a single model (e.g. based on the weakest cell in the battery pack), typically derived from laboratory experiments, to estimate values for the properties (e.g., SOX) for all cells in the battery pack. However, such techniques do not consider variability in operating conditions, degradation state, etc. among cells within the battery pack, which may result in an inaccurate estimation of pack properties.

Additionally, battery packs typically include series and parallel configurations of cells (e.g., lithium-ion cells). The utilization of series and parallel connections in a battery pack allows for achieving essentially any practical pack capacity, power and energy. However, preparing a battery pack for desired conditions by tuning capacity, power, and/or energy adds formidable complexity for the BMS. For instance, collecting useful data from the individual cells of a battery pack can be sophisticated due to the intricacy of the total system including embedded software, various hardware, and advanced science and technology from various fields such as physics, data science, machine-learning, networking/telemetry and software development. Additionally, it is generally impractical to install sensor(s) for all individual cells within a battery pack. Accordingly, the BMS hardware sensor data may not accurately represent cell-level data useful for modelling the state of individual cells in a battery pack.

The inventors have recognized and appreciated that existing techniques for estimating properties (e.g., SOX) for battery packs have a limited ability to accurately determine the SOX values for cells operating under different conditions within the battery pack, such as varying temperature based on their location within the pack, contact resistance, and aging effects. To this end, some embodiments of the present disclosure relate to techniques for decomposing battery pack sensor data received from the BMS to cell-based data that can be used for adaptive cell modeling. In some embodiments of the present disclosure, adaptive cell modeling may be used to produce one or more data sets for representative cells in the battery pack. The one or more data sets may be used to generate and/or train one or more models (e.g., one or more machine learning models) that may be used by the BMS to predict one or more battery system properties (e.g., SOC, SOH, SOP).

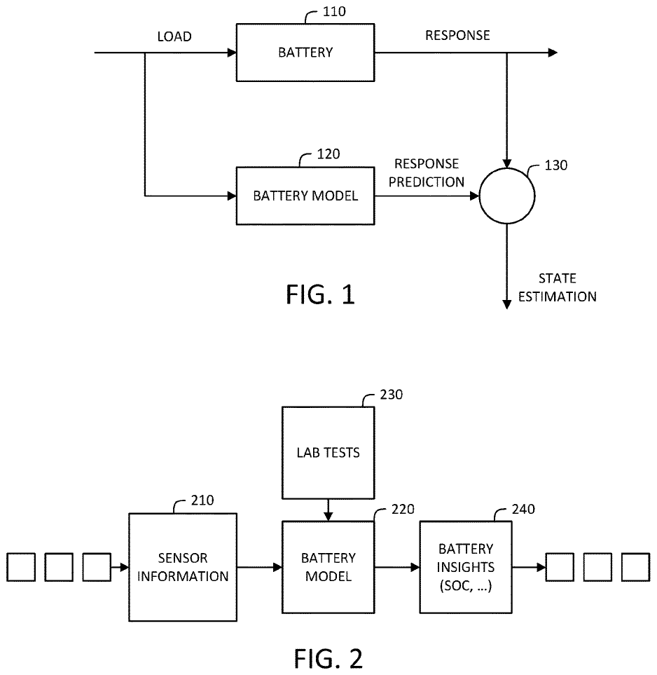

FIG. 1 schematically illustrates an adaptive cell model, in accordance with some embodiments of the present disclosure. In some conventional battery performance estimation techniques based on Coulomb counting, the response of the battery is used to estimate the battery properties, such as the battery's SOC. By contrast, an adaptive cell model configured in accordance with some embodiments of the present disclosure considers both the response of battery and a response prediction for one or more particular properties (e.g., SOC, SOH) output from a parameterized or “tailored” battery model to provide a state estimation of energy storage system performance. An example of such an adaptive cell model is schematically illustrated in FIG. 1. As shown in FIG. 1, load parameter values (e.g., current, voltage, ambient temperature, etc., as measured by one or more sensors and/or derived from one or more sensor measurements) are provided as input to battery system 110 to determine a response of the battery system under the current set of load conditions. The same load parameter values may be provided as input to a battery model 120 (also referred to herein as an “energy storage model”), configured to determine a response prediction and/or a property used to track cell degradation or detect battery failures. The response prediction output from the battery model 120 and the response measured from the battery system 110 may be combined at node 130 to provide a state estimation for a battery property with improved accuracy and/or anticipation compared to conventional techniques that, for example, use only the response measured from the battery system 110 to estimate system properties. In some embodiments of the present disclosure discussed in more detail below, the measured response output from battery system 110 and the response prediction output from battery model 120 may be combined at node 130 using one or more trained machine learning models (e.g., neural networks).

Throughout the lifespan of the battery system 110, the battery model 120 may be updated to more accurately reflect the current state of the battery (e.g., properties that describe the internal state of the battery, such as concentration of lithium ions in the electrodes of the battery at the current time) including effects due to degradation. Updating the battery model 120 may be performed in any suitable way. For example, the parameterization of the battery model 120 may be updated with new parameters based on current information about the state of the battery (e.g., degradation parameters). Additionally or alternatively, battery model 120 may be updated by substituting a different type of battery model 120 throughout the lifespan of the battery system 110. As described in more detail below, battery model 120 may include an empirical model, a physics-based model, or a combination of empirical and physics-based models. Examples of different types of battery model architectures for battery model 120 are also described in more detail below.

In some embodiments of the present disclosure, the manner in which the response output from battery system 110 and the response prediction output from battery model 120 are combined at node 130 may also be updated throughout the lifespan of the battery system 110. For example, when a neural network is used at node 130 to combine the response and response prediction information, the neural network parameters (e.g., weights) and/or architecture may be updated based, at least in part, on an evaluation of network architectures to accurately estimate the current state of battery system 110, information associated with other battery powered devices that include the same or a similar type of energy storage system as battery system 110, or any other suitable information.

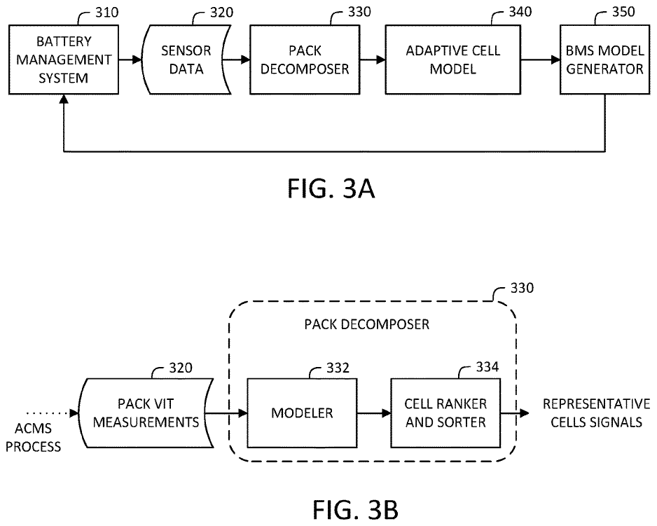

FIG. 2 schematically illustrates that an adaptive cell model, including a parameterized battery model 220, may be incorporated into a battery management system (BMS) and/or control system (e.g., electronic control unit (ECU), vehicle control unit (VCU), etc.). For instance the estimated battery insights 240 output from the battery model 220 in response to sensor information 210 provided as input to the battery model 220, may be used by a BMS of an electric vehicle to optimize one or more aspects (e.g., charging, discharging, failure analysis, etc.) of the energy storage system in the vehicle. As shown in FIG. 2, the battery model 220 may be tailored for a particular battery chemistry by performing a plurality of laboratory tests 230 that determine physical characteristics of the battery used to parameterize the battery model 220. As discussed above in connection with FIG. 1, throughout the lifespan of the battery, the battery model 220 may be updated to more accurately reflect the current state of the battery.

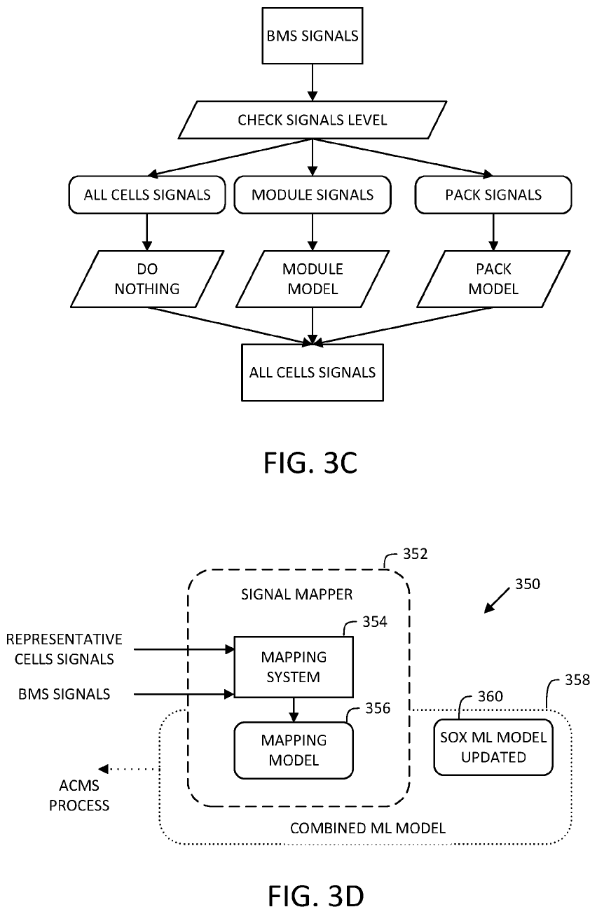

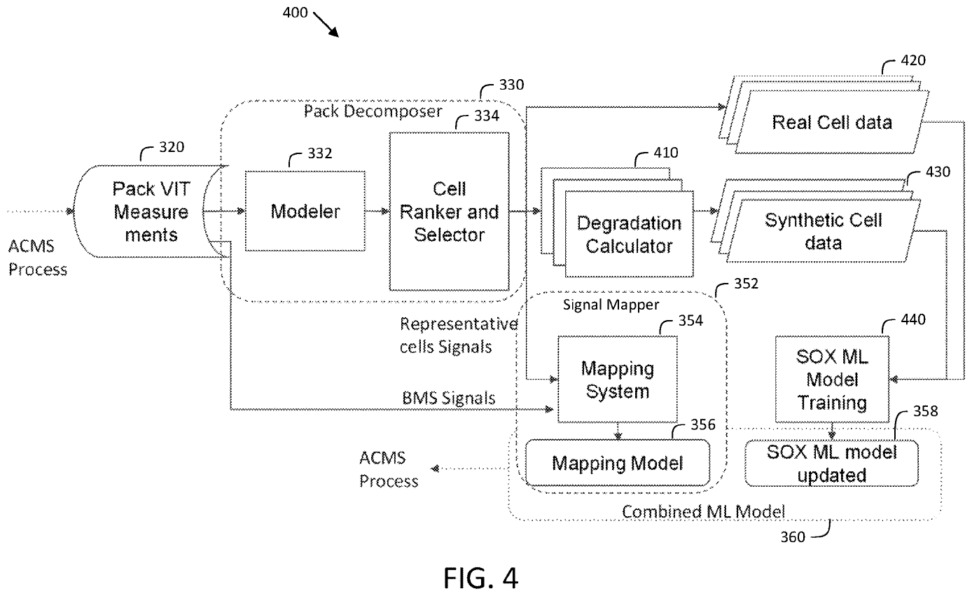

FIG. 3A schematically illustrates components of an architecture for dynamically updating a property (e.g., SOX) model, in accordance with some embodiments of the present disclosure. As shown in FIG. 3A, a battery management system (BMS) 310 may be configured to provide sensor data 320 to a pack decomposer 330. Any suitable sensor data 320 may be received from the BMS 310 and may be provided as input to pack decomposer 330. For instance, sensor data 320 may include voltage sensor data, current sensor data, and/or temperature sensor data (also referred to herein as “VIT measurements”) for individual cells and/or a group of cells (including, but not limited to, all cells) in the battery pack being monitored and controlled by the BMS 310. As discussed above, it is typically impractical (e.g., due to sensors' cost, data transmission requirements, data storage requirements, etc.) to include sensor(s) for each individual cell in a battery pack. Accordingly, sensor data 320 may characterize operating conditions of the cells of the battery pack at a coarser granularity than individual cells. The lack of cell-level sensor data may result in inaccuracy in property (e.g., SOX) estimation and/or fault detection algorithms that rely on the cell-level signals. In some embodiments, synthetic sensor data (e.g., not provided by the BMS) may be generated (e.g., by a middleware software layer) and may be provided as input to the pack decomposer 330. Pack decomposer 330 may be configured to map the sensor data 320 into cell-level sensor data that can be provided as input to an adaptive cell model, an example of which is described in connection with FIG. 4 below. Further examples of adaptive cell models are described in International Patent Application No. PCT/US2023/014981, which is hereby incorporated by reference in its entirety.

FIG. 3B schematically illustrates components of pack decomposer 330 in accordance with some embodiments of the present disclosure. For example, pack decomposer 330 may include modeler 332. Modeler 332 may include one or more pack-specific models (e.g., equations, look-up-tables, neural networks, etc.) for mapping the sensor data 320 (e.g., raw or processed sensor data) to cell-level data. For instance, modeler 332 may include one or more module and/or pack models that characterize (e.g., through laboratory testing) individual cells from beginning to end of life within the module or pack. FIG. 3C illustrates an example implementation of modeler 332 in accordance with some embodiments. As shown, the signal levels of each of the BMS signals (e.g., voltage, temperature, current, pressure, etc.) may be checked to determine whether the signal is a pack-level signal, a module-level signal, or a cell-level signal. If the signal is a cell-level signal no data transformation may be necessary. If the signal is a module-level signal, the signal may be processed by a module model to decompose the signal into a plurality of cell-level signals. If the signal is a pack-level signal, the signal may processed by a pack model to decompose the signal into a plurality of cell-level signals. In some embodiments, the pack-level signal may be decomposed into a plurality of module-level signals, and each of the module-level signals may be processed by a module model to decompose the module-level signals further into cell-levels signals. Collectively the cell-level signals output from modeler 332 may be cell-level data, which may be used to select representative cells for the battery pack. As an example, the BMS of a vehicle may provide 10 cycles of data (e.g., VIT data), and modeler 332 may decompose the 10 cycles of data into a vector with all cell-level signals in the same time length of the BMS data provided to the modeler 332 (e.g., profiles having 10 cycles of data). Non-limiting examples of cell-level data that may be output from modeler 332 include voltage profiles, current profiles, temperature profiles, pressure profiles, etc.

The cell-level data output from modeler 332 may be provided to cell ranker and selector 334. The inventors have recognized and appreciated that battery packs may generate a large amount of data, which may be challenging for an adaptive cell model to process in a timely and resource efficient manner. For instance, a battery pack with 28 battery cells may generate more than 10 million data points per day at a 1 Hz measurement rate. To reduce the amount of data used for adaptive modelling, some embodiments use cell ranker and selector 334 to select N cells as representative cells for the battery pack. Selecting representative cells may also enable the system to accurately represent the individual cells of a battery pack despite receiving fewer signals from the BMS 310. In this way, the selected and available data from the BMS may be leveraged to produce a generalized cell and/or pack model that is effective for describing representative cells and non-representative cells in the battery pack.

Any suitable number N of representative cells may be used. For instance, N may equal 1, 2, 5, 10, 20 or any other integer number of cells. In some embodiments, N may be selected as a particular percentage (e.g., 10-20%) of the total cells in the battery pack or may be selected in any other suitable way. In some embodiments, the number of representative cells may be selected based, at least in part, on a particular metric being calculated or estimated by the adaptive cell modelling. In some embodiments, the number of representative cells may be based on specific characteristics of the cells in the battery pack including, but not limited to, environment, relative location, symmetry, and whether one or more sensors are directly attached to the cell or not. In some embodiments, the number of representative cells may be selected based on a combination of factors including those listed herein and others. In this way, pack decomposer 330 may be configured to output N cell-level signals for N representative cells of the battery pack. For example, the N cell-level signals may be profiles (e.g., VIT profiles) for one or more charge cycles of the battery pack.

In some embodiments, cell ranker and selector 334 is configured to rank cell-level data output from modeler 332 according to various present and historical aspects to track cells with different amounts of degradation (e.g., weak cells). For example, the output of the ranking process may include the association of a score with the cell-level data. A BMS typically tracks cells that show minimum and maximum voltage signals across the battery pack. However, as discussed herein, such voltage signals may incorporate noise, contact and busbar resistance, etc., which negatively impacts the process of tracking weak cells. In some embodiments, cell ranker and selector 334 relies on present and/or historical signal values to score the cells in a battery pack based on different aspects. Example aspects include, but are not limited to, geometric and physical aspects such as voltage deviation from past to present, voltage deviation between cells, minimum voltage, maximum temperature, and location of the cell in the battery pack. Such a characterization of cells may facilitate understanding cells' performance from past to present and/or may isolate sensor noise when tracking weak cells in a battery pack.

In some embodiments, cell ranker and selector 334 is configured to group the cell-level data based on the score or other metric provided by the ranking process described above. Grouping the cell-level data may facilitate selection of N representative cells of a battery pack thereby providing for improved monitoring of the cells in the pack (e.g., the weakest cells in the pack) with reduced computational load relative to processing all of the cell-level data using an adaptive cell model, an example of which is described in more detail below. In some embodiments, the ranking and/or grouping performed by cell ranker and selector 334 may be based, at least in part, on the particular property that is being modeled. For instance, to accurately predict SOC, cells representing the strongest and weakest cells in the battery pack may be selected. As another example, certain properties may only require tracking a single representative cell (e.g., the weakest cell) in a battery pack. In such instances only a single representative cell corresponding to the weakest cell may be selected by cell ranker and selector 334. In some embodiments, cell ranker and selector 334 may perform ranking and/or selection of representative cells differently depending on the usage state of the battery pack. For instance, SOC prediction may be more challenging at the battery pack's beginning of life (BOL) compared to when the battery pack has been used for some amount of time. In such an instance, a different set of representative cells may be used for SOC prediction at BOL (possibly for use with a different prediction model) compared to later SOC prediction after the battery pack has been in use for some time. As another example, cells in a battery pack may degrade in unexpected ways, and different representative cells may be selected as the behavior and/or characteristics of the cells in the battery pack change. In some embodiments, information associated with one or more previous iterations of representative cell selection by cell ranker and selector 334 may be made available for a current representative cell selection process. It should be appreciated that other criteria for determining how cell ranker and selector 334 selects representative cells may alternatively be used.

Returning to the architecture shown in FIG. 3A, the N representative cell-level signals output from pack decomposer 330 may be provided as input to adaptive cell model 340. Each of the N representative cell-level signals may be a profile (e.g., a voltage profile, a temperature profile, a current profile) for a particular duration (e.g., one charge cycle, five charge cycles, 10 charge cycles, etc.). In some embodiments, a representative cell-level signal includes at least one full charge cycle including a discharge step and a charge step. In some embodiments, all of the N representative cell-level signals output from the pack decomposer 330 are simultaneously provided as input to the adaptive cell model 340 to generate a single output dataset based on all of the N representative cell-level signals. In other embodiments, each of the N representative cell-level signals is provided sequentially as input to the adaptive cell model 340 to generate N output datasets, each of which corresponds to one of the representative cells. In yet other embodiments, multiple instances of the adaptive cell model 340 (or components of the adaptive cell model) may be used, with each of the multiple instances being configured to process the cell-level data for one or more of the N representative cells. In such embodiments, representing the sensor data using N representative cells then performing concurrent adaptive modelling may improve processing time relative to linear processes. As described herein, adaptive cell model 340 may be configured to determine one or more characteristics (e.g., degradation parameters) of the energy storage system being monitored by BMS 310. Adaptive cell model 340 may also be configured in some embodiments to generate synthetic cell data for each of the representative cells, which may be used to generate and/or train an energy storage (e.g., battery) model. Example components of adaptive cell model 340 are described in more detail herein with regard to the architecture block diagram shown in FIG. 4.

As shown in FIG. 3A, the output of the adaptive cell model 340 may be provided to BMS model generator 350, which may be configured to generate one or more energy storage (e.g., battery) models for deployment on BMS 310. It should be appreciated that if, in some embodiments, the architecture of the one or more energy storage models does not change during an updating or retraining process described herein, only parameters of the model(s) may need to be sent to the BMS during deployment rather than the entire model(s). Due to the relatively limited processing power typically available on the BMS, the generated energy storage model(s) may be implemented as a lightweight model that ingests BMS sensor data and outputs an estimate of a property (e.g., SOX) of the energy storage system (e.g., the battery pack). In some embodiments, one or more of pack decomposer 330, adaptive cell model 340, and BMS model generator 350 may be implemented on a network-connected computing device (e.g., on one or more cloud computing devices). In this way, a lightweight SOX ML model may be deployed on the BMS, with the updating of the model being performed using cloud-based computing resources. In some embodiments, the lightweight SOX ML model deployed on the BMS may be updated based on cloud-computed data automatically without stoppage of service on the BMS.

FIG. 3D schematically illustrates components of BMS model generator 350 in accordance with some embodiments of the present disclosure. BMS model generator 350 may be configured to generate a combined ML model 360, which includes mapping model 356 and SOX ML model 358. The combined ML model 360 may be transferred to the BMS (e.g., BMS 310) for execution thereon as new BMS sensor data is sensed. As described below in connection with the architecture shown in FIG. 4, SOX ML model 358 may be trained based on cell-level data output from pack decomposer 330 and synthetic cell-level data output from adaptive cell model 340.

Mapping model 356 provided as the output of signal mapper 352 may translate BMS sensor signals to cell-level inputs that may be ingested by the trained SOX ML model 358. In some embodiments, mapping model 356 may be dynamic in that the model may be updated periodically (e.g., during each update/retraining of the SOX ML model 358). In this way the mapping model 356 may take into consideration degradation characteristics of the cells over time. In other embodiments, mapping model 356 may be static in that the model remains the same from beginning of life of the battery pack until end of life of the battery pack. As described above in connection with the description of pack decomposer 330, BMS sensor signals and/or synthetic sensor signals may report the operating conditions of a battery pack at different levels (e.g., pack level, module level, cell level). Signal mapper 352 includes a mapping system 354 that maps incoming BMS signals and/or synthetic sensor signals to representative cell signals that the SOX ML model 358 has been configured to receive as input. In some embodiments, the mapping provided in mapping system 354 is based on an understanding of the components in a particular battery pack, and may include both physics and data-driven approaches to perform the mapping. As shown in FIG. 3D, the input to the mapping system 354 may include representative cell signals output from the pack decomposer 330 and BMS signals received from the BMS 310. In some embodiments, the mapping system 354 may also include inputs from other components within the computing architecture shown in FIG. 4. For example, mapping system 354 may take into consideration degradation parameters (e.g., from degradation calculator 410) and/or synthetic cell-level data 430. The output of mapping system 354 may be used as training data to train mapping model 356 to be deployed, once trained, on the BMS along with SOX ML model 358 as part of combined ML model 360. By considering synthetic cell-level data 430, mapping system 354 may allow for the simulation of scenarios that are not described by the BMS sensor data, which may improve the robustness and/or generalizability of the trained mapping model 356 so that it can perform well in conditions on which it has not previously been trained. In some embodiments, signal mapper 352 may be implemented on a network (e.g., cloud-based) computing resource. As described herein, trained mapping model 356 may be used to determine a set of representative cell signals based on BMS signals (e.g., sensed cell signals and synthetic cell signals). For instance, if the BMS signals include a t length vector, trained mapping model 356 may be configured to output an N×t length vector, with N corresponding to a number of representative cell signals used to describe the battery pack. The N×t length vector output from trained mapping model 356 may be passed into the trained SOX ML model 358 for prediction of an SOX value. In this way, the trained mapping model 356 may be deployed on the BMS to transform BMS signals into data that can be ingested by the trained SOX ML model 358. In some embodiments trained mapping model 356 may be implemented as a machine learning model. In other embodiments, mapping model 356 may be implemented using one or more lookup tables and algebra to transform BMS signals into data for processing by the trained SOX ML model deployed on the BMS.

FIG. 4 illustrates an example architecture 400 for an adaptive modeling system in accordance with some embodiments of the present disclosure. As shown, architecture 400 includes several of the components already described in connection with FIGS. 3A-3C, such as pack decomposer 330, signal mapper 352, and combined ML model 360, and their functionality will not be repeated here for brevity. The architecture 400 shows additional details of adaptive cell model 340 including degradation calculator 410 and SOX ML model training component 440 that receives as input, cell data 420 and synthetic cell data 430, the latter of which is generated based on output from degradation calculator 410. Each of these components is described in more detail below.

The inventors have recognized that precisely estimating the degradation of cells within a battery pack in specific physical ways may provide a better understanding of the State of Health (SOH) of the battery pack, which in turn may impact the State of Charge (SOC), State of Power (SOP), and State of Temperature (SOT) predictions. For example, over time, pack imbalance may degrade individual cells within the pack in unique ways due to the fact that they are degrading in slightly different environments. In some embodiments, degradation calculator 410 may include one or more physics-based models that include parameters that can be updated based on input from pack decomposer 330. Use of physics-based models in degradation calculator 410 enables monitoring the change in physics parameters (e.g., resistance growth) of representative cells in a monitored battery pack. As described herein, the output of pack decomposer 330 is a set of sensor signals for N representative cells in a battery pack being monitored. Degradation calculator 410 may adaptively tune one or more physics-based model parameters based on the received cell-level signals for the N representative cells received from pack decomposer 330. The tuned physics-based models in the degradation calculator 410 may be used to predict future patterns of cell characteristics (e.g., future cell degradation trajectories) for the N representative cells by generating synthetic cell data 430 corresponding to the representative cells. Degradation calculator 410 may also receive historical data (e.g., historical profile data for one or more cells of the battery pack), which may be used to generate the synthetic cell data 430. For example, if it is determined that a particular representative cell in a battery pack has 10% less capacity compared to when it was manufactured, the synthetic cell data 430 may reflect that reduced capacity. In some embodiments, synthetic cell data 430 represents a profile (e.g., a voltage profile, a current profile, a temperature profile, etc.) for a duration t (e.g., the length of one or more charge cycles). In some embodiments, the profile represented in the synthetic cell data 430 may be predicted, at least in part, based on past usage of the energy storage system (e.g., past driving history data). In other embodiments, the profile represented in the synthetic cell data 430 may be predicted based, at least in part, on information about expected future usage of the energy storage system (e.g., expected future driving behavior). For instance, information about a future route to be driven may be compared with one or more previously-driven routes and a past route most similar (e.g., in terms of geography, traffic, time of day, day of the week, weather, etc.) may be used to predict the expected future usage of the energy storage system during the future route.

In some embodiments of the present disclosure, the synthetic cell data 430 may reflect a “higher-than-typical” resolution of temperature data across the cells in a battery pack. BMS temperature sensors can be quantized to poor resolution (e.g., 1 °C resolution). Some embodiments employ an ML-based temperature map that utilizes the known size dimensions and pack configuration as the approximate temperature sensor positions and the sensors' values to predict higher resolution cell-level temperature data for each individual cell. For example, instead of 1 °C resolution, a 0.1 °C resolution may be achieved. Temperature values may be predicted from nonlinear equations. Higher resolution temperature data may provide higher quality context to the model during prediction. Therefore, an SOX model with access to this data may gain greater capability in differentiating between similar events, without increasing its SOX ML model memory requirements or architecture.

As shown, both the cell data 420 and the synthetic cell data 430 may be used by SOX ML model training component 440 to train an SOX ML model (e.g., SOX ML model 358) to predict cell-level SOX values. In this way the SOX ML model 358 may be trained to take into account both current state data reflected in the cell-level data 420 and future state data for the representative cells corresponding to future driving patterns, as reflected in the synthetic cell data 430. Continuing with the example above of a reduced capacity representative cell, the synthetic cell data 430 may reflect the reduced capacity and the trained SOX ML model 358 may in turn reflect that when the representative cell is charged, it may not charge to full capacity (e.g., it may only charge to 90% capacity rather than 100% capacity). Enabling the trained SOX ML model 358 to understand future charge cycles of the representative cells in this way may result in more accurate SOX estimates.

As described above, some existing models for predicting SOX of a battery pack are trained on data corresponding to a single cell in the pack, typically the weakest cell. The inventors have recognized that the failure of such models to properly characterize the differences in degradation properties for individual cells in the battery pack results in inaccurate SOX predictions. Some embodiments of the present disclosure employ SOX ML model training component 440 that trains an SOX ML model based on cell-level data for representative cells in the battery pack. As shown in FIG. 4, the cell-level data includes cell-level data 420 and synthetic cell-level data 430 output from degradation calculator 410. In some embodiments, processing by the adaptive cell model that includes degradation calculation and synthetic cell generation components may be performed N times for each of the N representative cell signals output from the pack decomposer 330, with the result being N sets of synthetic cell data for each of the representative cells. The N sets of cell-level data 420 and the N sets of synthetic cell-level data 430 (each of which may include M number of charge cycles, where M≥1) may be added to a training queue associated with SOX ML model training component 440 and SOX ML model 358 may be trained based on the data in the training queue, resulting in an SOX prediction model that takes into consideration current and future expected cell-level property differences for individual cells within a battery pack. In some embodiments, the SOX ML model 358 may be trained sequentially on the cell-level data for each of the N representative cells in any order. In other embodiments, an identifier (e.g., that identifies the representative cell or a group of representative cells that it represents) for each representative cell may be provided to SOX ML model 358 during training to guide the model to understand which data is associated with which representative cell in the battery pack. The inventors have recognized that the trained SOX ML model 358 may tend to be more influenced by recent training data rather than older training data. Accordingly, in some embodiments, one or more certain representative cell types (e.g., the weakest cell in the pack) may be identified prior to training and the cell-level data corresponding to the identified representative cell type(s) may be arranged in the training queue as desired. For example, the representative cell corresponding to the weakest cell in the pack may be identified and the cell-level data for that cell may be placed last in the sequentially training queue, which may result in the model being optimized to predict on the weakest cell in the pack.

It should be appreciated that the cell-level data 420 may include “raw” sensor data (either directly from the BMS or decomposed using pack decomposer) or data derived from the raw sensor data. For instance, in some embodiments, the cell-level data 420 includes derived sensed profile data averaged over a moving window. When training with the cell-level data 420, the target cell-level SOX values may be obtained using one or more physics-informed models. For example, target SOC values (as an example of SOX) may be generated using a more accurate (but computationally slower) physics-informed model. Such a physic-informed model may be too computationally intensive to be practically implemented on the BMS or used in real-time.

The SOX ML model 358 once trained is configured to ingest cell-level data and output one or more cell-level SOX values. In some embodiments, the cell-level SOX value(s) output from SOX ML model 358 may be aggregated (e.g., via an averaging function, a minimum/maximum function, etc.) or otherwise post-processed to extract a pack-level SOX value for a battery pack. As described above, sensor data provided by the BMS does not typically correspond to individual cell-level data but instead corresponds to sensor data for an ensemble of cells within a battery pack. To transform BMS sensor data to cell-level data that can be used with the trained SOX ML model 358, some embodiments include signal mapper 352. Signal mapper 352 may be configured to understand how the BMS sensor data characterizes the individual cells of the pack in terms of SOX properties, and may select or compute data that will be used by the trained SOX ML model 358 for prediction as described above.

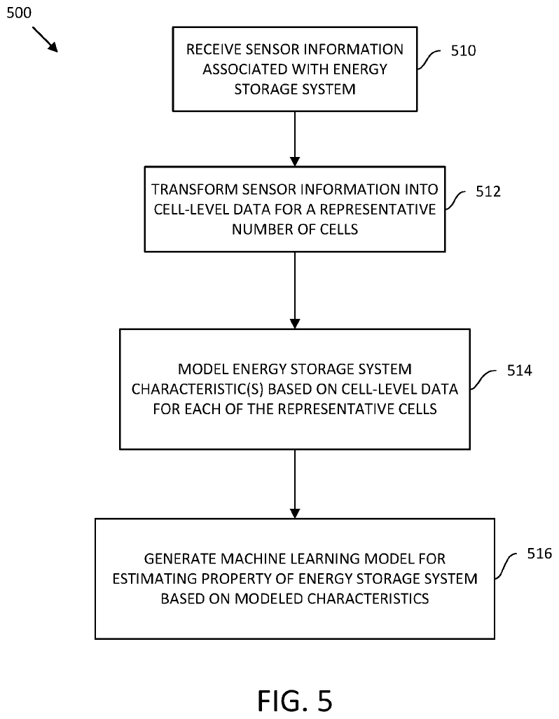

FIG. 5 is flowchart of a process 500 for generating an ML model for predicting properties (e.g., SOX) of an energy storage system in accordance with some embodiments of the present disclosure. Process 500 begins in act 510, where sensor information associated with the energy storage system is received. For instance, the energy storage system may be a battery pack that includes a plurality of cells (e.g., grouped into modules). The received sensor information may include, for example, voltage, current, temperature, and or pressure sensor signals for individual cells or groups of cells in the pack.

Process 500 then proceeds to act 512, where the received sensor information is transformed into cell-level data for a representative number of cells in the energy storage system. For instance, the received sensor data signals may be decomposed using one or more models configured based on laboratory data into cell-level data signals that represent the individual cells of a battery pack. Different models may be employed depending on the type of sensor data that is received. For instance, if the sensor data corresponds to individual cell-level data, no transformation may be required. However, if the sensor data corresponds to module-level data (e.g., from a group of cells less than all of the cells in the battery pack), then a module model may be used to transform the module-level data into cell-level data. When the sensor data corresponds to pack-level data, a pack-level model may be used to transform the pack-level data into cell-level data. After using appropriate models to transform the received sensor data into cell-level data, the cell-level data may be ranked (e.g., by assigning scores to the cell-level data) and the ranked cell-level data may be grouped to produce cell-level data for N representative cells within the battery pack, as described above.

Process 500 then proceeds to act 514, where one or more energy storage system characteristics are modeled based on the cell-level data for each of the representative cells. For instance, as described herein, the cell-level data for the N representative cells may be processed by an adaptive cell model architecture that generates synthetic cell-level data for the representative cells. The adaptive cell model may include a degradation calculator that uses physics-based models of cell degradation to determine degradation characteristics for the representative cells. As new cell-level data is provided to the adaptive cell model, parameters for the physics-based models may be tuned to reflect the current state of the cells in the battery pack to be able to more accurately predict future performance of the cells as reflected in synthetic cell-level data generated base d on the output of the degradation calculator.

Process 500 then proceeds to act 516, where a machine learning (ML) model for predicting a property of the energy storage system is generated based on the modeled energy storage system characteristics. For instance, as described above, an SOX ML model may be trained based on cell-level data from the BMS and synthetic cell-level data output from an adaptive cell modeling process, resulting in a trained SOX ML model generated in act 516. It should be appreciated that the adaptive cell modelling architecture shown in FIG. 4 may be used to generate separate trained SOX ML models for each of a plurality of properties. For example, separate trained ML models for predicting SOC, SOH and SOP may be generated using the adaptive cell modelling processes described herein, and each of the trained SOC, SOH and SOP models may be deployed on the BMS to predict properties for the energy storage system during its use. The trained SOX ML model may be run multiple times on the BMS to predict the relevant SOX values, in keeping with the behavior of the BMS.

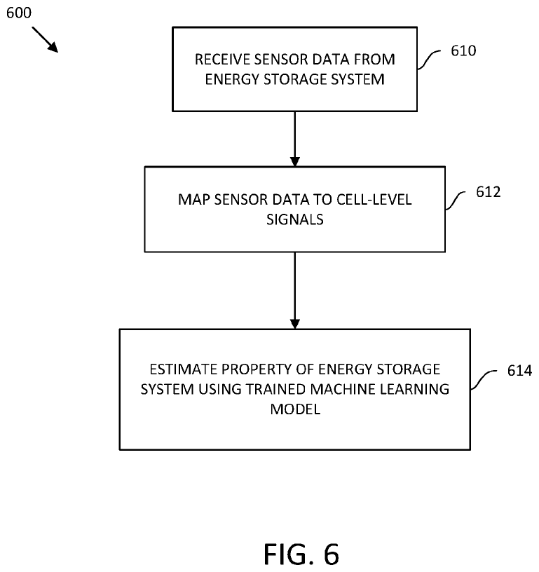

FIG. 6 illustrates a process 600 for predicting a property(e.g., SOX) of an energy storage system (e.g., a battery pack) using an ML model trained in accordance with one or more of the techniques described herein. Process 600 begins in act 610, where sensor data is received from the energy storage system. As described herein, a BMS may be configured to monitor performance of a battery pack using one or more sensors. The sensor data may include voltage sensor data, current sensor data, temperature sensor data, and/or pressure sensor data. The sensor data may include sensor data associated with individual cells in the battery pack, modules including multiple cells in the battery pack, or the entire battery pack.

Process 600 then proceeds to act 612, where the received sensor data is mapped to cell-level signals that the trained SOX ML model is configured to ingest. For instance, a trained mapping model resident on the BMS may receive the sensor data and translate the sensor data to cell-level data as described herein. Process 600 then proceeds to act 614, where one or more properties (e.g., SOX) of the energy storage system are predicted using the cell-level signals and the trained SOX ML model. In this way, one or more properties of a battery pack can be predicted by the BMS (e.g., in real-time) based on an updated SOX ML model that takes into consideration differences in individual cells within the battery.

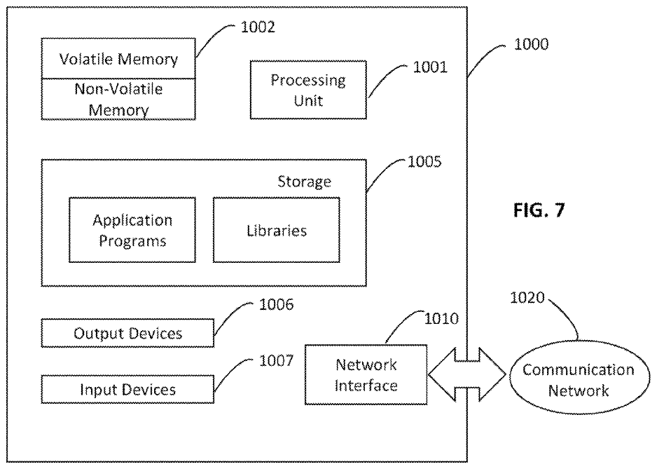

FIG. 7 shows, schematically, an illustrative computer 1000 on which any aspect of the present disclosure may be implemented.

In the example of FIG. 7, the computer 1000 includes a processing unit 1001 having one or more computer hardware processors and one or more articles of manufacture comprising at least one non-transitory computer-readable medium (e.g., a memory 1002 that may include, for example, volatile and/or non-volatile memory). The memory 1002 may store one or more instructions to program the processing unit 1001 to perform any of the functionalities described herein. The computer 1000 may also include other types of non-transitory computer-readable media, such as a storage 1005 (e.g., one or more disk drives) in addition to the memory 1002. The storage 1005 may also store one or more application programs and/or resources used by application programs (e.g., software libraries), which may be loaded into the memory 1002. Thus, the memory 1002 and/or the storage 1005 may serve as one or more non-transitory computer-readable media storing instructions for execution by the processing unit 1001.

The computer 1000 may have one or more input devices and/or output devices, such as devices 1006 and 1007 illustrated in FIG. 7. These devices may be used, for instance, to present a user interface. Examples of output devices that may be used to provide a user interface include printers, display screens, and other devices for visual output, speakers and other devices for audible output, braille displays and other devices for haptic output, etc. Examples of input devices that may be used for a user interface include keyboards, pointing devices (e.g., mice, touch pads, and digitizing tablets), microphones, etc. For instance, the input devices 1007 may include a microphone for capturing audio signals, and the output devices 1006 may include a display screen for visually rendering, and/or a speaker for audibly rendering, recognized text.

In the example of FIG. 7, the computer 1000 also includes one or more network interfaces (e.g., a network interface 1010) to enable communication via various networks (e.g., a network 1020). Examples of networks include local area networks (e.g., an enterprise network), wide area networks (e.g., the Internet), etc. Such networks may be based on any suitable technology operating according to any suitable protocol, and may include wireless networks and/or wired networks (e.g., fiber optic networks).

Having thus described several aspects of at least one embodiment, it is to be appreciated that various alterations, modifications, and improvements will readily occur to those skilled in the art. Such alterations, modifications, and improvements are intended to be within the spirit and scope of the present disclosure. Accordingly, the foregoing descriptions and drawings are by way of example only.

The above-described embodiments of the present disclosure can be implemented in any of numerous ways. For example, the embodiments may be implemented using hardware, software, or a combination thereof. When implemented in software, the software code may be executed on any suitable processor or collection of processors, whether provided in a single computer, or distributed among multiple computers.

Also, the various methods or processes outlined herein may be coded as software that is executable on one or more processors running any one of a variety of operating systems or platforms. Such software may be written using any of a number of suitable programming languages and/or programming tools, including scripting languages and/or scripting tools. In some instances, such software may be compiled as executable machine language code or intermediate code that is executed on a framework or virtual machine. Additionally, or alternatively, such software may be interpreted.

The techniques described herein may be embodied as a non-transitory computer-readable medium (or multiple such computer-readable media) (e.g., a computer memory, one or more floppy discs, compact discs, optical discs, magnetic tapes, flash memories, circuit configurations in Field Programmable Gate Arrays or other semiconductor devices, or other non-transitory, tangible computer-readable medium) encoded with one or more programs that, when executed on one or more processors, perform methods that implement the various embodiments of the present disclosure described above. The computer-readable medium or media may be portable, such that the program or programs stored thereon may be loaded onto one or more different computers or other processors to implement various aspects of the present disclosure as described above.

The terms “program” or “software” are used herein to refer to any type of computer code or set of computer-executable instructions that may be employed to program one or more processors to implement various aspects of the present disclosure as described above. Moreover, it should be appreciated that according to one aspect of this embodiment, one or more computer programs that, when executed, perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Program modules may include routines, programs, objects, components, data structures, etc. that perform particular tasks or implement particular abstract data types. Functionalities of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields to locations in a computer-readable medium, so that the locations convey how the fields are related. However, any suitable mechanism may be used to relate information in fields of a data structure, including through the use of pointers, tags, and/or other mechanisms that establish how the data elements are related.

Various features and aspects of the present disclosure may be used alone, in any combination of two or more, or in a variety of arrangements not specifically described in the foregoing, and are therefore not limited to the details and arrangement of components set forth in the foregoing description or illustrated in the drawings. For example, aspects described in one embodiment may be combined in any manner with aspects described in other embodiments.

Also, the techniques described herein may be embodied as methods, of which examples have been provided. The acts performed as part of a method may be ordered in any suitable way. Accordingly, embodiments may be constructed in which acts are performed in an order different from illustrated, which may include performing some acts simultaneously, even though shown as sequential acts in illustrative embodiments.

Use of ordinal terms such as “first,” “second,” “third,” etc. in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

Also, the phraseology and terminology used herein is for the purpose of description and should not be regarded as limiting. The use of “including,” “comprising,” “having,” “containing,” “involving,” “based on,” “according to,” “encoding,” and variations thereof herein, is meant to encompass the items listed thereafter and equivalents thereof as well as additional items.

1. A computer-implemented method, comprising:
receiving sensor data associated with an energy storage system; and
transforming, using at least one hardware computer processor, the sensor data into cell-level data for a number of representative cells in the energy storage system.

2. The method of claim 1, further comprising:
generating, using at least one model of cell degradation and the cell-level data, synthetic cell-level data for each of the representative cells;
training a machine learning (ML) model based on the cell-level data and the synthetic cell-level data, wherein the trained ML model is configured to infer a property of the energy storage system based on cell-level data; and
outputting the trained ML model.

3. The method of claim 1, wherein the energy storage system is a battery pack and the received sensor data is associated with the battery pack.

4. The method of claim 3, wherein
the sensor data includes module sensor data associated with a module of the battery pack, the module including a plurality of cells, and
transforming the sensor data into cell-level data for a representative number of cells comprises using a module model to transform the module sensor data into cell-level data.

5. The method of claim 3, wherein
the sensor data includes pack sensor data associated with all cells in the battery pack, and
transforming the sensor data into cell-level data for a representative number of cells comprises using a pack model to transform the pack sensor data into cell-level data.

6. The method of claim 1, wherein the sensor data includes one or more of voltage sensor data, current sensor data, temperature sensor data, or pressure sensor data.

7. The method of claim 1, wherein the sensor data comprises time-series data.

8. The method of claim 1, wherein transforming the sensor data into cell-level data for a number of representative cells in the energy storage system comprises:
processing the sensor data using one or more models to produce cell-level data for a plurality of cells in the energy storage system;
generating groups of cells based on the cell-level data; and
selecting a representative cell from each of the groups of cells to produce the cell-level data for a number of representative cells in the energy storage system.

9. The method of claim 8, wherein transforming the sensor data into cell-level data for a number of representative cells in the energy storage system further comprises:
assigning scores to the plurality of cells in the energy storage system, wherein generating the groups of cells is performed based, at least in part, on the scores.

10. The method of claim 2, wherein generating synthetic cell-level data for each of the representative cells comprises:
providing the cell-level data as input to the at least one model of cell degradation, the at least one model of cell degradation including degradation parameters that describe how cells in the energy storage system degrade over time; and
generating the synthetic cell-level data based, at least in part, on an output of the at least one model of cell degradation.

11. The method of claim 2, wherein training the ML model comprises sequentially training the ML model based on the cell-level data and the synthetic cell-level data for each of the representative cells.

12. The method of claim 2, wherein outputting the trained ML model comprises transferring the trained ML model to a battery management system associated with the energy storage system.

13. The method of claim 12, further comprising:
transferring to the battery management system, a mapping model configured to translate sensor data from the battery management system into cell-level data for representative cells of the energy storage system.

14. The method of claim 13, further comprising:
generating the mapping model based, at least in part, on second cell-level data for the number of representative cells and second sensor data.

15. The method of claim 14, wherein generating the mapping model is further based, at least in part, on at least one degradation parameter associated with the at least one model of cell degradation.

16. The method of claim 2, wherein the trained ML model is configured to infer one or more of state of charge (SOC), state of health (SOH), state of power (SOP), or state of temperature (SOT) of the energy storage system.

17. A computer-implemented method for estimating a property of an energy storage system, comprising:
receiving sensor data associated with the energy storage system;
transforming, using a mapping model executing on at least one hardware computer processor, the sensor data into cell-level data for representative cells of the energy storage system;
providing the cell-level data as input to a trained machine learning (ML) model; and
estimating the property of the energy storage system using the trained ML model.

18. The method of claim 17, further comprising:
receiving from a network-connected computing device, an updated trained ML model and an updated mapping model, wherein
transforming the sensor data into cell-level data for representative cells of the energy storage system is performed using the updated mapping model, and
estimating the property of the energy storage system is based, at least in part, on an output of the updated trained ML model.

19. The method of claim 17, wherein the property is selected from the group consisting of state of charge (SOC), state of health (SOH), state of power (SOP), and state of temperature (SOT) of the energy storage system.

20. The method of claim 17, wherein the sensor data includes one or more of voltage sensor data, current sensor data, temperature sensor data, or pressure sensor data.

21. The method of claim 17, wherein the sensor data comprises time-series data.

22. A computer-implemented method, comprising:
receiving first sensor data associated with an energy storage system;
transforming, using at least one hardware computer processor, the first sensor data into cell-level data for a number of representative cells in the energy storage system;
generating a mapping model configured to transform second sensor data into cell-level data for representative cells in the energy storage system, wherein the mapping model is generated based, at least in part, on the cell-level data for the number of representative cells and the first sensor data; and
outputting the generated mapping model.

23. The method of claim 22, wherein generating the mapping model is further based, at least in part, on at least one degradation parameter associated with at least one model of cell degradation.

24. The method of claim 22, wherein outputting the generated mapping model comprises transferring the generated mapping model to a battery management system associated with the energy storage system.

25. A system comprising:
at least one computer processor; and
at least one computer-readable medium having stored thereon instructions which, when executed, program the at least one computer processor to perform the method of any of claims 1-24.

26. At least one computer-readable medium having stored thereon instructions which, when executed, program at least one computer processor to perform the method of any of claims 1-24.
